(19) United States
(12) Patent Application Publication
(10) Pub. No.: US 2016/0061925 A1
(43) Pub. Date: Mar. 3, 2016

(54) AUTOMATED OPTIMIZATION OF MRI IMAGE ACQUISITION PARAMETERS

(71) Applicant: ASPECT IMAGING LTD., Shoham (IL)

(72) Inventor: Uri RAPOPORT, Moshav Ben Shemen (IL)

(73) Assignee: ASPECT IMAGING LTD., Shoham (IL)

(21) Appl. No.: 14/840,003

(22) Filed: Aug. 30, 2015

Related U.S. Application Data
(60) Provisional application No. 62/044,249, filed on Aug. 31, 2014.

(51) Int. Cl. G01R 33/58; G01R 33/48; G01R 33/50

(52) U.S. Cl. CPC G01R 33/58; G01R 33/50; G01R 33/4828

(57) ABSTRACT

A method for automatic determination of optimal Magnetic Resonance Imaging (MRI) acquisition parameters for imaging in an MRI instrument a sample containing two types of tissue, tissue A and tissue B, wherein said method comprises: determining T_{1A}, T_{2A}, T_{1B}, T_{2B}, ρ_{A}, and ρ_{B}, where ρ represents the density of NMR-active nuclei being probed; setting initial values of T_{R} and T_{E}; determining the signal intensities S_{A} and S_{B} from the equation S=ρE₁E₂, where E₁=1−e^{-T}^{_{R}}^{/T}^{₁} and E₂=e^{-T}^{_{E}}^{/T}^{₂}; calculating the contrast-to-noise ratio for tissue A in the presence of tissue B (CNR_{AB}) from the equation

$${CNR}_{AB} = \frac{P ( {S}_{A} - {S}_{B} )}{\sqrt{{T}_{R}}} ,$$

where P is a proportionality constant; and, determining optimal values of T_{R} and T_{E} that yield a maximum value of CNR_{AB}(T_{R},T_{E}). In other embodiments of the invention, the method includes optimization of additional acquisition parameters. An MRI system in which the method is implemented so that acquisition parameters can be optimized without any intervention by the system operator is also disclosed.

### FIELD OF THE INVENTION

This patent relates to methods of acquisition of images using Magnetic Resonance Imaging. In particular, it relates to automated methods for optimizing image acquisition parameters, especially in permanent-magnet MRI systems.

### BACKGROUND OF THE INVENTION

Magnetic Resonance Imaging (MRI) has become a standard diagnostic tool. Despite its wide use, the actual operation of an MRI instrument remains to a large extent more of an art than of a science, due to the inherent complexity of the methodology. The quality of the image obtained during MRI depends critically on the choice of acquisition parameters, yet the optimization of these parameters is frequently beyond the abilities of the average operator. There has thus been a significant effort made to reduce the time and effort needed to find optimal acquisition parameters, particularly by automating the determination of these parameters.

For example, U.S. Pat. No. 4,694,250 discloses a method for optimizing acquisition parameters in which, for a given T₁, T₂, and proton density, the variance or standard deviation between a calculated image and the actual image as a function of scan parameters is minimized.

U.S. Pat. No. 6,781,375 discloses a method for optimizing at least one scan parameter in which a plurality of preparatory images are obtained using different values of an “image quality parameter.” The operator then selects the best image, and the scan parameters used to obtain that image are then used for the final image.

U.S. Pat. No. 7,715,899 discloses a method for optimizing acquisition parameters in which a low-resolution full-body scan is performed, a region of interest is identified, and the acquisition of parameters for a subsequent high-resolution scan are then determined. In addition to the requirement for a preliminary full-body scan, the patent does not disclose any details of the algorithm used to find these parameters or of the equations that might be used for finding the optimal parameters. Furthermore, no mention is made of critical parameters such as the contrast-to-noise ratio (CNR), or of the possibility of predictions based on T₁ or T₂, measured or estimated.

U.S. Pat. Appl. Pub. No. 2007/0276221 discloses a method for generating MRI images that comprises acquiring a reference scan, providing the MRI apparatus with a target value of a specific scan parameter, and determining an optimum scan parameter set according to the target value of that specific scan parameter.

An automated method for obtaining MRI images in which the determination of optimal acquisition parameters that does not require a full-body scan or input from the operator remains a long-felt, yet unmet, need.

### SUMMARY OF THE INVENTION

It is an object of the present invention to meet this need. In particular, a method is presented for automated optimization of acquisition parameters for obtaining an image of a desired tissue type in the presence of a second tissue type.

It is therefore an object of the present invention to disclose a method for automatic determination of optimal Magnetic Resonance Imaging (MRI) acquisition parameters for imaging in an MRI instrument a sample containing two types of tissue, tissue A and tissue B, wherein said method comprises: determining T_{1A}, T_{2A}, T_{1B}, T_{2B}, ρ_{A}, and ρ_{B}, where ρ represents the density of NMR-active nuclei being probed; setting initial values of T_{R} and T_{E}; determining the signal intensities S_{A} and S_{B} from the equation S=ρE₁E₂, where E₁=1−e^{-T}^{_{R}}^{/T}^{₁} and E₂=e^{-T}^{_{E}}^{/T}^{₂}; calculating the contrast-to-noise ratio for tissue A in the presence of tissue B (CNR_{AB}) from the equation

$${CNR}_{AB} = \frac{P ( {S}_{A} - {S}_{B} )}{\sqrt{{T}_{R}}} ,$$

where P is a proportionality constant; and, determining optimal values of T_{R} and T_{E} that yield a maximum value of CNR_{AB}(T_{R},T_{E}).

It is an additional object of the present invention to disclose such a method, wherein said NMR-active nuclei are protons.

In some embodiments of the invention, said step of determining T_{1A}, T_{2A}, T_{1B}, T_{2B}, ρ_{A}, and ρ_{B} comprises importing at least one of T_{1A}, T_{2A}, T_{1B}, T_{2B}, ρ_{A}, and ρ_{B} from a database of known values. In some embodiments of the invention, said step of determining T_{1A}, T_{2A}, T_{1B}, T_{2B}, ρ_{A}, and ρ_{B} comprises determining at least one of T_{1A}, T_{2A}, T_{1B}, T_{2B}, ρ_{A}, and ρ_{B} from a preliminary MRI scan performed on said sample.

It is a further object of the present invention to disclose the method as defined in any of the above, wherein P=1.

It is a further object of the present invention to disclose the method as defined in any of the above, wherein said step of determining optimal values of T_{R} and T_{E} comprises: systematically varying T_{R} and T_{E} independently over predetermined ranges of values; storing CNR_{AB}(T_{R},T_{E}) for each pair of values T_{R}, T_{E}; and, defining as optimal values T_{R} and T_{E} those values that yield said maximum value of CNR_{AB}(T_{R},T_{E}). In some embodiments of the invention, said step of systematically varying T_{R} and T_{E} independently over predetermined ranges of values comprises varying T_{E} over the range 10-100 ms and varying T_{R} over the range 0.5-5 s.

It is a further object of the present invention to disclose the method as defined in any of the above, wherein said step of determining optimal values of T_{R} and T_{E} comprises using a preprogrammed optimization algorithm to find said maximum value of CNR_{AB}(T_{R},T_{E}). In some embodiments of the invention, said preprogrammed optimization algorithm is selected from the group consisting of simulated annealing, branch and bound methods, and Monte Carlo sampling methods.

It is a further object of the present invention to disclose the method as defined in any of the above, wherein tissue A and tissue B are two tissue types selected from the group consisting of gray matter, white matter, and cerebrospinal fluid.

It is a further object of the present invention to disclose the method as defined in any of the above, wherein tissue A is tumor tissue and tissue B is normal tissue. In some embodiments of the invention, tissue A and tissue B are located within a single organ.

It is a further object of the present invention to disclose the method as defined in any of the above, wherein tissues A and B are two different organs within a field of view of said MRI instrument.

It is a further object of the present invention to disclose the method as defined in any of the above, wherein said step of determining optimal values of T_{R} and T_{E} comprises: varying T_{R} and T_{E} within ranges typical of a scan type selected from the group consisting of ranges typical of a T₁-weighted scan and ranges typical of a T₂-weighted scan; and, determining said maximum value of CNR_{AB}(T_{R},T_{E}); whereby said method determines automatically whether a T₁-weighted scan or a T₂-weighted scan provides said maximum CNR_{AB}. In some embodiments of the invention, said step of determining optimal values of T_{R} and T_{E} comprises at varying T_{R} and T_{E} over at least one set of ranges bounded by a set of boundary conditions selected from the group consisting of T_{R}<0.75 s, T_{E}<40 ms and T_{R}>2 s, T_{E}<100 ms.

It is a further object of the present invention to disclose the method as defined in any of the above, comprising determining optimal values of n additional acquisition parameters Pₙ, n≧1. In some embodiments of the invention, said additional acquisition parameters are selected from the group consisting of flip angle, RF pulse length, and RF pulse amplitude.

It is a further object of the present invention to disclose such a method, wherein said step of determining optimal values of n additional acquisition parameters Pₙ comprises: varying each of said parameters Pₙ over a predetermined range; determining said optimal T_{R} and T_{E} for each value of Pₙ; and, determining said optimal value of Pₙ as a value of Pₙ that yields said maximum value of CNR_{AB}(T_{R},T_{E}).

It is a further object of the present invention to disclose such a method, wherein said step of determining optimal values of n additional acquisition parameters Pₙ comprises determining the optimal values of T_{R}, T_{E}, and P₁ . . . Pₙ that yield a maximum value of CNR_{AB}(T_{R}, T_{E}, P₁ . . . Pₙ). In some embodiments of the invention, said step of determining determining the optimal values of T_{R}, T_{E}, and P₁ . . . Pₙ that yield a maximum value of CNR_{AB}(T_{R}, T_{E}, P₁ . . . Pₙ) comprises using an optimization algorithm that finds the maximum CNR_{AB} over the function space of T_{R}, T_{E}, P₁ . . . Pₙ. In some embodiments of the invention, said optimization algorithm is selected from the group consisting of simulated annealing, branch and bound methods, and Monte Carlo sampling methods.

It is a further object of the present invention to disclose the method as defined in any of the above, wherein said method is implemented as part of the control and or acquisition software of an MRI system. In some preferred embodiments of the invention, said MRI system is a permanent-magnet MRI system.

It is a further object of the present invention to disclose an MRI system comprising a control and/or acquisition subsystem programmed to perform the method as defined in any of the above. In some preferred embodiments of the invention, said MRI system is a permanent-magnet MRI system.

It is a further object of the present invention to disclose an MRI system as defined in any of the above, wherein said control and/or acquisition subsystem is programmed to perform the method as defined in any of the above without any intervention by an operator of said system.

### BRIEF DESCRIPTION OF THE FIGURES

The invention will now be described with reference to the figures, wherein:

FIG. 1 presents a flowchart of the steps in one embodiment of the method herein disclosed for optimizing the contrast-to-noise ratio of an MRI image as a function of T_{R} and T_{E}; and,

FIG. 2 presents a flowchart of the steps in one embodiment of the method herein discloses for optimizing the contrast-to-noise ratio of an MRI image as a function of T_{R}, T_{E}, and at least one other acquisition parameter.

### DETAILED DESCRIPTION OF THE PREFERRED EMBODIMENTS

In the following description, various aspects of the invention will be described. For the purposes of explanation, specific details are set forth in order to provide a thorough understanding of the invention. It will be apparent to one skilled in the art that there are other embodiments of the invention that differ in details without affecting the essential nature thereof. Therefore the invention is not limited by that which is illustrated in the figure and described in the specification, but only as indicated in the accompanying claims, with the proper scope determined only by the broadest interpretation of said claims.

As used herein, subscripts “A” and “B” refer to a parameter specific to the appropriate substance. For example, T_{1A} is the T₁ of substance A, while T_{1B} is the T₁ of substance B. Except for the addition of subscript “A” or “B,” all symbols and abbreviations used herein are used according to standard MRI/NMR practice.

It is known in the art (Ting, Y.-L.; Bendel, P. J. Magn. Reson. Imaging 1992, 3, 393-399) that the CNR between two different tissues can be expresses as the ratio between the difference in the signal intensities and the image noise. The signal intensity of tissue A (denoted as S_{A}) is given by eq (1):

S_{A}=ρ_{A}E_{1A}E_{2A} (1)

where ρ_{A} is the density of NMR-active nuclei being probed (in general, these will be protons) of tissue A and E_{1A} and E_{2A} are given by eqs (2a) and (2b), respectively:

E_{1A}=1−e^{-T}^{_{R}}^{/T}^{_{1A}} (2a)

E_{2A}=e^{-T}^{_{E}}^{/T}^{_{2A}} (2b)

These equations assume that T_{E}<<T_{R}, T₁.

The CNR between tissue A and a second tissue B (CNR_{AB}) is given by eq (3):

$${CNR}_{AB} = \frac{P ( {S}_{A} - {S}_{B} )}{\sqrt{{T}_{R}}} \qquad ( 3 )$$

where P is a proportionality constant that may be set to 1, and the division by the square root of T_{R} normalizes the expression to a constant imaging time.

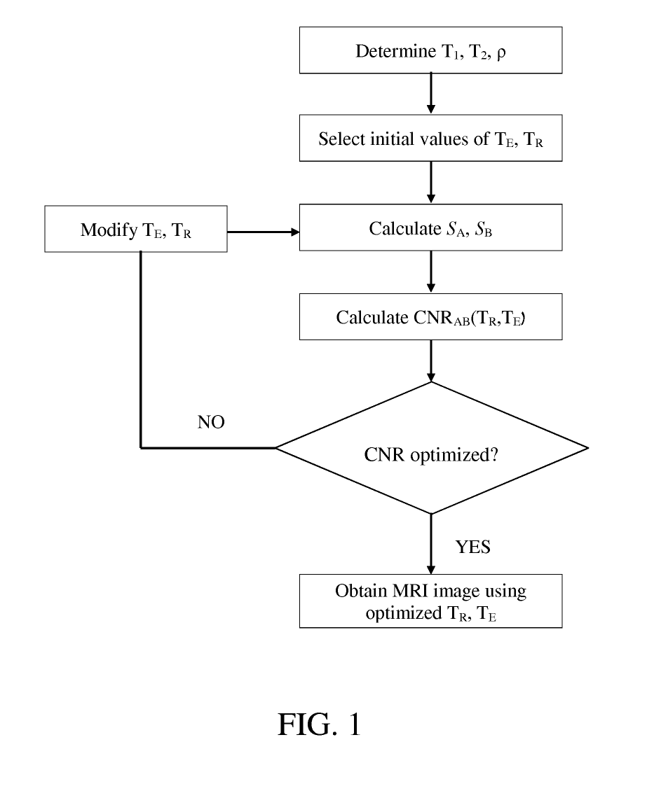

In the method disclosed herein, T₁, T₂, and ρ can be determined experimentally for each tissue type from a preliminary scan, or they can be imported from a database of previously measured values. Once T₁, T₂, and ρ for each tissue type are known, T_{R} and T_{E} are then optimized for imaging tissue A in the presence of tissue B by maximizing of CNR_{AB} as a function of T_{R} and T_{E}. Any optimization algorithm known in the art may be used. As non-limiting examples, a “brute-force” approach may be taken in which a series of preliminary scans is taken in which T_{R} and T_{E} are systematically and independently varied over predetermined ranges of reasonable values (e.g. 10-100 ms for T_{E} and 0.5-5 s for T_{R}) and the pair of T_{R}, T_{E} values that give the maximum CNR_{AB} values are used. Other optimization algorithms that vary T_{R} and T_{E} in preliminary scans to find the maximum of CNR_{AB}, such as simulated annealing, branch and bound methods, Monte Carlo sampling methods, etc., may be used as well. Reference is now made to FIG. 1, which presents a flowchart outlining the steps of the method.

The method herein described may be used to find the optimal T_{R} and T_{E} for the detection of any tissue type A in the presence of tissue type B. Non-limiting examples include maximizing the CNR for gray matter vs. white matter (or vice versa) or for either one of gray matter or white matter vs. cerebrospinal fluid in a brain scan, maximizing the CNR for tumor vs. normal tissue (in some embodiments, both tissue types are located within a single organ of interest), maximizing the CNR for one organ over another when both are within the field of view of the MRI instrument, etc.

It is within the scope of the invention wherein the method herein disclosed is used to determine automatically whether a T₁-weighted scan or a T₂-weighted scan provides the optimal contrast between the two tissue types. In this embodiment of the invention, T_{R} and T_{E} are optimized within ranges typical of either a T₁-weighted scan (e.g. T_{R}<0.75 s, T_{E}<40 ms) or of a T₂-weighted scan (e.g. T_{R}>2 s, T_{E}<100 ms) and determining which set T_{R} or T_{E} provides the maximum CNR_{AB}.

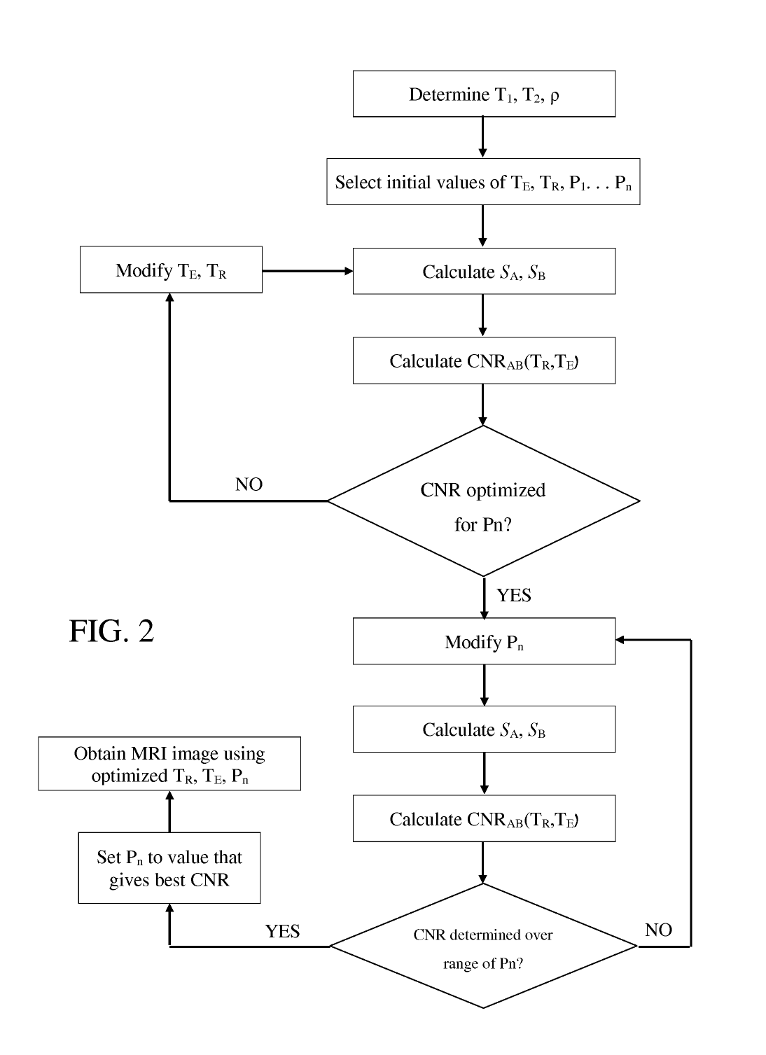

It is also within the scope of the invention wherein the method herein disclosed is used to optimize automatically other acquisition parameters Pₙ including, but not limited to, flip angle, RF pulse length, and RF pulse amplitude. In one exemplary and non-limiting embodiment, for each parameter Pₙ to be optimized, a loop is added to the optimization algorithm in which the parameter is varied within predetermined limits and the optimal T_{R} and T_{E} are found as described above. For each value of Pₙ, the maximum CNR_{AB}(T_{R},T_{E}) is recorded. The value of Pₙ that yields the maximum value of CNR_{AB}(T_{R},T_{E}) is used in the acquisition of the MRI image. Reference is now made to FIG. 2, which presents a flowchart illustrating this embodiment of the method. In other embodiments of the method, CNR_{AB} is treated as a function of (T_{R}, T_{E}, ρ₁ . . . Pₙ) and an optimization algorithm is used that finds the maximum CNR_{AB} over the function space of all of the acquisition parameters of interest. As with the optimization of CNR_{AB}(T_{R},T_{E}) disclosed above, any optimization algorithm known in the art (e.g. simulated annealing, branch-and-bound methods, Monte Carlo methods, etc.) may be used to find the maximum value of CNR_{AB}(T_{R}, T_{E}, P₁ . . . Pₙ).

In preferred embodiments of the method, it is implemented as part of the MRI system's control and acquisition software. In other embodiments, it is implemented as a standalone software package. That is, the optimization algorithm is performed automatically by the MRI system without any intervention from the system operator.

It is within the scope of the invention to disclose an MRI instrument in which the acquisition system is programmed to perform the optimization method herein disclosed as part of the image acquisition software. In preferred embodiments of the invention, the MRI instrument that includes a control system programmed to perform the method herein disclosed is a permanent-magnet MRI system.

What is claimed is:

1. A method for automatic determination of optimal Magnetic Resonance Imaging (MRI) acquisition parameters for imaging in an MRI instrument a sample containing two types of tissue, tissue A and tissue B, wherein said method comprises:
determining T_{1A}, T_{2A}, T_{1B}, T_{2B}, ρ_{A}, and ρ_{B}, where ρ represents the density of NMR-active nuclei being probed;
setting initial values of T_{R} and T_{E};
determining the signal intensities S_{A} and S_{B} from the equation S=ρE₁E₂, where E₁=1−e^{-T}^{_{R}}^{/T}^{₁} and E₂=e^{-T}^{_{E}}^{/T}^{₂};
calculating the contrast-to-noise ratio for tissue A in the presence of tissue B (CNR_{AB}) from the equation
$${CNR}_{AB} = \frac{P ( {S}_{A} - {S}_{B} )}{\sqrt{{T}_{R}}} ,$$
where P is a proportionality constant; and,
determining optimal values of T_{R} and T_{E} that yield a maximum value of CNR_{AB}(T_{R},T_{E}).

2. The method according to claim 1, wherein said NMR-active nuclei are protons.

3. The method according to claim 1, wherein said step of determining T_{1A}, T_{2A}, T_{1B}, T_{2B}, ρ_{A}, and ρ_{B} comprises importing at least one of T_{1A}, T_{2A}, T_{1B}, T_{2B}, ρ_{A}, and ρ_{B} from a database of known values.

4. The method according to claim 1, wherein said step of determining T_{1A}, T_{2A}, T_{1B}, T_{2B}, ρ_{A}, and ρ_{B} comprises determining at least one of T_{1A}, T_{2A}, T_{1B}, T_{2B}, ρ_{A}, and ρ_{B} from a preliminary MRI scan performed on said sample.

5. The method according to claim 1, wherein P=1.

6. The method according to claim 1, wherein said step of determining optimal values of T_{R} and T_{E} comprises:
systematically varying T_{R} and T_{E} independently over predetermined ranges of values;
storing CNR_{AB}(T_{R},T_{E}) for each pair of values T_{R}, T_{E}; and,
defining as optimal values T_{R} and T_{E} those values that yield said maximum value of CNR_{AB}(T_{R},T_{E}).

7. The method according to claim 7, said step of systematically varying T_{R} and T_{E} independently over predetermined ranges of values comprises varying T_{E} over the range 10-100 ms and varying T_{R} over the range 0.5-5 s.

8. The method according to claim 1, wherein said step of determining optimal values of T_{R} and T_{E} comprises using a preprogrammed optimization algorithm to find said maximum value of CNR_{AB}(T_{R},T_{E}).

9. The method according to claim 8, wherein said preprogrammed optimization algorithm is selected from the group consisting of simulated annealing, branch and bound methods, and Monte Carlo sampling methods.

10. The method according to claim 1, wherein tissue A and tissue B are two tissue types selected from the group consisting of gray matter, white matter, and cerebrospinal fluid.

11. The method according to claim 1, wherein tissue A is tumor tissue within an organ of interest and tissue B is normal tissue.

12. The method according to claim 11, in which tissue A and tissue B are located within a particular organ.

13. The method according to claim 1, wherein tissues A and B are two different organs within a field of view of said MRI instrument.

14. The method according to claim 1, wherein said step of determining optimal values of T_{R} and T_{E} comprises:
varying T_{R} and T_{E} within ranges typical of a scan type selected from the group consisting of ranges typical of a T₁-weighted scan and ranges typical of a T₂-weighted scan; and,
determining said maximum value of CNR_{AB}(T_{R},T_{E});
whereby said method determines automatically whether a T₁-weighted scan or a T₂-weighted scan provides said maximum CNR_{AB}.

15. The method according to claim 14, wherein said step of determining optimal values of T_{R} and T_{E} comprises at varying T_{R} and T_{E} over at least one set of ranges bounded by a set of boundary conditions selected from the group consisting of T_{R}<0.75 s, T_{E}<40 ms and T_{R}>2 s, T_{E}<100 ms.

16. The method according to claim 1, comprising determining optimal values of n additional acquisition parameters Pₙ, n≧1.

17. The method according to claim 16, wherein said additional acquisition parameters are selected from the group consisting of flip angle, RF pulse length, and RF pulse amplitude.

18. The method according to claim 16, wherein said step of determining optimal values of n additional acquisition parameters Pₙ comprises:
varying each of said parameters Pₙ over a predetermined range;
determining said optimal T_{R} and T_{E} for each value of Pₙ; and,
determining said optimal value of Pₙ as a value of Pₙ that yields said maximum value of CNR_{AB}(T_{R},T_{E}).

19. The method according to claim 16, wherein said step of determining optimal values of n additional acquisition parameters Pₙ comprises determining the optimal values of T_{R}, T_{E}, and P₁ . . . Pₙ that yield a maximum value of CNR_{AB}(T_{R}, T_{E}, P₁ . . . Pₙ).

20. The method according to claim 19, wherein said step of determining determining the optimal values of T_{R}, T_{E}, and P₁ . . . Pₙ that yield a maximum value of CNR_{AB}(T_{R}, T_{E}, P₁ . . . Pₙ) comprises using an optimization algorithm that finds the maximum CNR_{AB} over the function space of T_{R}, T_{E}, P₁ . . . Pₙ.

21. The method according to claim 20, wherein said optimization algorithm is selected from the group consisting of simulated annealing, branch and bound methods, and Monte Carlo sampling methods.

22. The method according to any one of claims 1-21, wherein said method is implemented as part of the control and or acquisition software of an MRI system.

23. The method according to claim 22, wherein said MRI system is a permanent-magnet MRI system.

24. An MRI system, comprising a control and/or acquisition subsystem programmed to perform the method according to any one of claims 1-21.

25. The MRI system according to claim 24, wherein said MRI system is a permanent-magnet MRI system.

26. The MRI system according to claim 24, wherein said control and/or acquisition subsystem is programmed to perform the method according to any one of claims 1-21 without any intervention by an operator of said system.
